(19) United States
(12) Patent Application Publication
(10) Pub. No.: US 2016/0126391 A1
(43) Pub. Date: May 5, 2016

(54) SOLAR CELL MODULE AND MANUFACTURING METHOD THEREOF

(71) Applicant: BYD COMPANY LIMITED, Shenzhen (CN)

(72) Inventors: Xiang SUN, Shenzhen (CN); Shencun WANG, Shenzhen (CN); Jinxin XUE, Shenzhen (CN); Zhanfeng JIANG, Shenzhen (CN)

(73) Assignee: BYD COMPANY LIMITED, Shenzhen (CN)

(21) Appl. No.: 14/928,863

(22) Filed: Oct. 30, 2015

(30) Foreign Application Priority Data
Oct. 31, 2014 (CN) 201410606601.7
Oct. 31, 2014 (CN) 201410606607.4
Oct. 31, 2014 (CN) 201410606675.0
Oct. 31, 2014 (CN) 201410606700.5
Oct. 31, 2014 (CN) 201410608469.3
Oct. 31, 2014 (CN) 201410608576.6
Oct. 31, 2014 (CN) 201410608577.0
Oct. 31, 2014 (CN) 201410608579.X
Oct. 31, 2014 (CN) 201410608580.2
Feb. 17, 2015 (CN) 201510085666.6
Apr. 30, 2015 (CN) 201510217551.8
Apr. 30, 2015 (CN) 201510217573.4
Apr. 30, 2015 (CN) 201510217609.9
Apr. 30, 2015 (CN) 201510217616.9
Apr. 30, 2015 (CN) 201510217617.3
Apr. 30, 2015 (CN) 201510217625.8
Apr. 30, 2015 (CN) 201510217687.9
Apr. 30, 2015 (CN) 201510218489.4
Apr. 30, 2015 (CN) 201510218535.0
Apr. 30, 2015 (CN) 201510218562.8
Apr. 30, 2015 (CN) 201510218563.2
Apr. 30, 2015 (CN) 201510218574.0
Apr. 30, 2015 (CN) 201510218635.3
Apr. 30, 2015 (CN) 201510218697.4
Apr. 30, 2015 (CN) 201510219182.6
Apr. 30, 2015 (CN) 201510219353.5
Apr. 30, 2015 (CN) 201510219366.2
Apr. 30, 2015 (CN) 201510219378.5
Apr. 30, 2015 (CN) 201510219417.1
Apr. 30, 2015 (CN) 201510219436.4
Apr. 30, 2015 (CN) 201510219540.3
Apr. 30, 2015 (CN) 201510219565.3
Apr. 30, 2015 (CN) 201510221302.6
Apr. 30, 2015 (CN) 201520276309.3
Apr. 30, 2015 (CN) 201520276534.7
Apr. 30, 2015 (CN) 201520277480.6
Apr. 30, 2015 (CN) 201520278149.6
Apr. 30, 2015 (CN) 201520278183.3
Apr. 30, 2015 (CN) 201520278409.X
Apr. 30, 2015 (CN) 201520280778.2
Apr. 30, 2015 (CN) 201520280868.1
Aug. 31, 2015 (CN) 201510546524.5

(51) Int. Cl. H01L 31/05; H01L 31/048; H01L 31/049

(52) U.S. Cl. CPC H01L 31/0508; H01L 31/049; H01L 31/0488

(57) ABSTRACT

The present disclosure discloses a solar cell module and a manufacturing method thereof. The solar cell module includes an upper glass plate, a front adhesive layer, a solar cell array, a back adhesive layer and a back plate superposed in sequence. The back plate is a water vapor insulation back plate having a transmission rate less than or equal to 0.1 mg/m²/day; the solar cell array comprises a plurality of cells and conductive wires, adjacent cells being connected by the conductive wires; the cells are provided with secondary grid lines on front surfaces thereof, and the conductive wires are welded with the secondary grid lines by a welding layer with an alloy which contains Sn and Bi. The solar cell module according to the embodiments of the present disclosure can improve the connection effect of the conductive wires and the cells, so as to guarantee the photoelectric conversion efficiency. Moreover, the upper glass plate, the front adhesive layer, the back adhesive layer and the lower glass or metal plate may seal the welding layer effectively to protect the cell array, so as to slow down the corrosion of the solar cell module and to prolong the service life.

The present application claims priority to the following 42 Chinese applications, the entireties of all of which are hereby incorporated by reference.
1. Chinese Patent Application No. 201410608576.6, filed Oct. 31, 2014;
2. Chinese Patent Application No. 201410606607.4, filed Oct. 31, 2014;
3. Chinese Patent Application No. 201410606601.7, filed Oct. 31, 2014;
4. Chinese Patent Application No. 201410606675.0, filed Oct. 31, 2014;
5. Chinese Patent Application No. 201410608579.X, filed Oct. 31, 2014;
6. Chinese Patent Application No. 201410608577.0, filed Oct. 31, 2014;
7. Chinese Patent Application No. 201410608580.2, filed Oct. 31, 2014;
8. Chinese Patent Application No. 201410606700.5, filed Oct. 31, 2014;
9. Chinese Patent Application No. 201410608469.3, filed Oct. 31, 2014;
10. Chinese Patent Application No. 201510085666.6, filed Feb. 17, 2015;
11. Chinese Patent Application No. 201510217625.8, filed Apr. 30, 2015;
12. Chinese Patent Application No. 201510217609.9, filed Apr. 30, 2015;
13. Chinese Patent Application No. 201510217687.9, filed Apr. 30, 2015;
14. Chinese Patent Application No. 201520276309.3, filed Apr. 30, 2015;
15. Chinese Patent Application No. 201510219182.6, filed Apr. 30, 2015;
16. Chinese Patent Application No. 201510217617.3, filed Apr. 30, 2015;
17. Chinese Patent Application No. 201520278183.3, filed Apr. 30, 2015;
18. Chinese Patent Application No. 201510217573.4, filed Apr. 30, 2015;
19. Chinese Patent Application No. 201510219540.3, filed Apr. 30, 2015;
20. Chinese Patent Application No. 201510218489.4, filed Apr. 30, 2015;
21. Chinese Patent Application No. 201510218563.2, filed Apr. 30, 2015;
22. Chinese Patent Application No. 201510219565.3, filed Apr. 30, 2015;
23. Chinese Patent Application No. 201510219436.4, filed Apr. 30, 2015;
24. Chinese Patent Application No. 201510218635.3, filed Apr. 30, 2015;
25. Chinese Patent Application No. 201520277480.6, filed Apr. 30, 2015;
26. Chinese Patent Application No. 201510219366.2, filed Apr. 30, 2015;
27. Chinese Patent Application No. 201520278409.X, filed Apr. 30, 2015;
28. Chinese Patent Application No. 201510218697.4, filed Apr. 30, 2015;
29. Chinese Patent Application No. 201510219417.1, filed Apr. 30, 2015;
30. Chinese Patent Application No. 201510221302.6, filed Apr. 30, 2015;
31. Chinese Patent Application No. 201510219353.5, filed Apr. 30, 2015;
32. Chinese Patent Application No. 201520280778.2, filed Apr. 30, 2015;
33. Chinese Patent Application No. 201510219378.5, filed Apr. 30, 2015;
34. Chinese Patent Application No. 201520280868.1, filed Apr. 30, 2015;
35. Chinese Patent Application No. 201510218574.0, filed Apr. 30, 2015;
36. Chinese Patent Application No. 201510217616.9, filed Apr. 30, 2015;
37. Chinese Patent Application No. 201520278149.6, filed Apr. 30, 2015;
38. Chinese Patent Application No. 201510218562.8; filed Apr. 30, 2015;
39. Chinese Patent Application No. 201510218535.0, filed Apr. 30, 2015;
40. Chinese Patent Application No. 201510217551.8, filed Apr. 30, 2015;
41. Chinese Patent Application No. 201520276534.7, filed Apr. 30, 2015; and
42. Chinese Patent Application No. 201510546524.5, filed Aug. 31, 2015.

### FIELD

The present disclosure relates to the field of solar cells, and more particularly, to solar cell modules and manufacturing methods thereof.

### BACKGROUND

The main structure of the conventional cell array is that a silver primary grid line of a cell is welded with a back surface of an adjacent cell; the main component of the paste for manufacturing the primary grid lines is expensive silver, and the welding strip is mostly a copper wire plated with a Sn—Pb alloy; an ordinary module utilizes EVA as an encapsulation film, and a polymer material as a back plate, which causes some defects in the long run.

First, the back plate is made of the polymer material with a certain water vapor transmission rate, such that the moisture and corrosive gas in the environment may penetrate into the module, then erode the cells and the welding strip, and reduce the service life of the module. Second, the TPT back plate with better performance is high in cost, while the ordinary non-Tedler lower glass or metal plate tends to yellow, crack and dust, which affects the efficiency and service life of the module, and results in lightening streaks formed on the module. Third, the polymer material has poor abrasion resistance, such that in the windy and dusty areas, the anti-aging layer on the back plate is easy to be abraded, and hence the PET layer (or copper function layer) is exposed. The PET layer is easier to be abraded, thereby weakening the abrasion resistance of the whole module. Fourth, the back plate is made of a flexible material, and the back surface basically has no physical protection for the cell, such that the cell tends to crack when being pressed or hit. Fifth, EVA is added with a UV absorbent, but the UV absorbent will be gradually worn out in long time of exposure. In the action of UV light and moistures, EVA will be degraded and yellow, which reduces the power output of the module, and produce small molecules (e.g. acetic acids), which erodes the welding strip and cells, and reduces the service life and efficiency of the module.

In addition, the cells and the welding strips are usually welded by the Sn—Pb alloy, which may cause environmental pollution due to the presence of Pb (a non-green material), and thus hinder wide application.

### SUMMARY

The present disclosure is based on discoveries and understanding of the applicant to the following facts and problems.

In the prior art, the primary grid lines and the secondary grid lines of the solar cells are made of expensive silver paste, which causes a complicated manufacturing process of the primary grid lines and the secondary grid lines and high cost. When the cells are connected into a module, the primary grid lines on the front surface of a cell are welded with back electrodes of another adjacent cell by a solder strip. Consequently, the welding of the primary grid lines is complicated, and the manufacturing cost of the cells is high.

However, in the prior art, two primary grid lines are usually disposed on the front surface of the cell, and formed by applying silver paste to the front surface of the cell. The primary grid lines have a great width (for example, up to over 2 mm), which consumes a large amount of silver, and makes the cost high.

Consequently, from the perspective of lowering the cost and reducing the shading area, the prior art replaces the silver primary grid lines printed on the cell with metal wires, for example, copper wires. The copper wires are welded with the secondary grid lines to output the current. Since the silver primary grid lines are no longer used, the cost can be reduced considerably. The copper wire has a smaller diameter to reduce the shading area, so the number of the copper wires can be raised up to 10. This kind of cell may be called a cell without primary grid lines, in which the metal wire replaces the silver primary grid lines and solder strips in the traditional solar cells.

In the field of solar cells, the structure of the solar cell is not complicated, but each component is crucial. The production of the primary grid lines takes various aspects into consideration, such as shading area, electric conductivity, equipment, process, cost, etc., and hence becomes a difficult and hot issue in the solar cell technology. In the market, a solar cell with two primary grid lines is replaced with a solar cell with three primary grid lines in 2007 through huge efforts of those skilled in the art. A few factories came up with a solar cell with four primary grid lines around 2014. The concept of multiple primary grid lines is put forward in the recent years, but there is no fairly mature product.

The present disclosure provides a solar cell without primary grid lines, which needs neither primary grid line nor sold strip disposed on the cells, and thus lowers the cost. The solar cell without primary grid lines can be commercialized for mass production, easy to manufacture with simple equipment, especially in low cost, and moreover have high photoelectric conversion efficiency. As for the solar cell without primary grid lines disclosed in the related art, the metal wire can be welded with the cell. The metal wire is relatively fine, so there is relatively great stress, such that the binding force between the metal wire and the cell is highly required, and correspondingly the welding layer is highly required. In the related art, the Sn—Pb alloy is usually employed, but the alloy may pollute the environment due to Pb which is not a green material. After a long time research, the inventor of the present disclosure finds that the Sn—Bi alloy has a good application foreground. The Sn—Bi alloy is low in cost, but has a critical defect in a long-term use that the metal wire in an ordinary module tends to be darkened in less than one month. Through test and analysis, SnBi is oxidized most easily, which indicates that the alloy cannot be applied in practical products, yet the low cost and pollution of the SnBi alloy makes it become an alloy composition of the welding layer available to the process.

Referring to FIG. 15 that shows a curve of polarization of the Sn—Bi alloy and the Sn—Pb alloy, the testing condition includes: an area of about 20 mm² of a test sample that is immersed into a dilute acetic acid (pH value being about 6); Sn used as the comparison electrode (i.e. the metal Sn is the reference electrode); and an area of about 0.2 mm² of the respective research electrode of Sn—Bi and Sn—Pb. In FIG. 15, the x-coordinate represents voltage (unit: V), and the y-coordinate represents current (unit: mA); in a forward voltage segment, the greater the polarization current generated under the same polarization voltage, the more easily the alloy is oxidized.

Through analysis on the polarization curve, the Sn—Bi alloy (represented by line a in FIG. 15) is less easily oxidized than the Sn—Pb alloy (represented by line b in FIG. 15) under the same conditions. That is, the Sn—Bi alloy is more stable, and the Sn—Bi alloy has a lower water vapor transmission rate than the Sn—Pb alloy. Specifically in the solar cell according to the present disclosure, the Sn—Pb alloy is commonly used for welding in the art, but it is possible to employ the Sn—Bi alloy with higher stability for welding. Theoretically speaking, the back plate used in welding by the Sn—Pb alloy can fully satisfy the anti-oxidation requirement for the Sn—Bi alloy used in welding.

However, after a long-term research, the inventor of the present disclosure finds that the oxidation rate of the Sn—Bi alloy is higher than that of the Sn—Pb alloy in a humid environment. Hence, the inventor conducts an intensive study on the oxidation rate of the Sn—Bi alloy and the moisture transmission performance of the back plate, and it turns out that when the water vapor transmission rate of the back plate is larger than 0.1 mg/m²/day, the oxidation rate of the Sn—Bi alloy is sharply increased with the increase of the water vapor transmission rate; when the water vapor transmission rate of the back plate is less than or equal to 0.1 mg/m²/day, the oxidation rate of the Sn—Bi alloy does not change considerably as the water vapor transmission rate varies.

Consequently, the inventor select a material with the water vapor transmission rate of less than or equal to 0.1 mg/m²/day for the back plate, which may effectively prevent the Sn—Bi alloy from being oxidized, such that the moisture and corrosive gas in the environment cannot enter the interior of the solar cell, to avoid discoloration and darkening of the Sn—Bi alloy due to oxidation in common encapsulating conditions, and the service life of the solar cell will not be affected. The Sn—Bi alloy is effectively protected from discoloring, which reduces the corrosion of the solar cell and prolongs the service life thereof.

The present disclosure seeks to solve at least one of the problems existing in the related art to at least some extent.

Thus, the present disclosure provides a solar cell module that is easy to manufacture in low cost, and improves the photoelectric conversion efficiency.

The present disclosure further provides a method for manufacturing the solar cell module.

According to a first aspect of embodiments of the present disclosure, a solar cell module includes an upper glass plate, a front adhesive layer, a solar cell array, a back adhesive layer and a back plate superposed in sequence. The back plate is a water vapor insulation back plate having a transmission rate less than or equal to 0.1 mg/m²/day; the solar cell array includes a plurality of cells and conductive wires, adjacent cells being connected by the conductive wires; the cells are provided with secondary grid lines on front surfaces thereof, and the conductive wires are welded with the secondary grid lines by a welding layer with an alloy which contains Sn and Bi.

In the solar cell module according to embodiments of the present disclosure, the secondary grid lines and the conductive wires on the cells are connected by the welding layer with the alloy containing Sn and Bi, so as to improve the effect of connecting the conductive wires and the cells, and to guarantee the photoelectric conversion efficiency. Surprisingly, this kind of welding layer may be applied better in the water vapor insulation back plate. The upper glass plate, the front adhesive layer, the back adhesive layer and the water vapor insulation back plate (like a glass or metal plate) may seal the welding layer effectively to avoid the phenomenon of discoloration and to protect the cell array, so as to slow down the corrosion of the solar cell module and to prolong the service life at the low cost.

According to a second aspect of embodiments of the present disclosure, a method for manufacturing a solar cell module includes: superposing an upper glass plate, a front adhesive layer, the cell array, a back adhesive layer and a water vapor insulation back plate in sequence, in which a front surface of a cell faces the front adhesive layer, a back surface thereof faces the back adhesive layer, and laminating them to obtain the solar cell module, and in which the solar cell array includes a plurality of cells and conductive wires, adjacent cells being connected by the conductive wires; the cells are provided with secondary grid lines on front surfaces thereof, the conductive wires being welded with the secondary grid lines by a welding layer with an alloy containing Sn and Bi.

### BRIEF DESCRIPTION OF THE DRAWINGS

FIG. 1 is a plan view of a solar cell array according to an embodiment of the present disclosure;

FIG. 2 is a longitudinal sectional view of a solar cell array according to an embodiment of the present disclosure;

FIG. 3 is a transverse sectional view of a solar cell array according to embodiments of the present disclosure;

FIG. 4 is a schematic view of a metal wire for forming a conductive wire according to embodiments of the present disclosure;

FIG. 5 is a plan view of a solar cell array according to another embodiment of the present disclosure;

FIG. 6 is a plan view of a solar cell array according to another embodiment of the present disclosure;

FIG. 7 is a schematic view of a metal wire extending reciprocally according to embodiments of the present disclosure;

FIG. 8 is a schematic view of two cells of a solar cell array according to embodiments of the present disclosure;

FIG. 9 is a schematic view of a solar cell array formed by connecting, via a metal wire, the two cells according to FIG. 8;

FIG. 10 is a schematic view of a solar cell module according to embodiments of the present disclosure;

FIG. 11 is a sectional view of part of the solar cell module according to FIG. 10;

FIG. 12 is a schematic view of a solar cell array according to another embodiment of the present disclosure;

FIG. 13 is a schematic view of assembling a solar cell module according to the present disclosure;

FIG. 14 is a schematic view of a metal wire under strain in Comparison Example 1;

FIG. 15 is a curve of polarization of a Sn—Bi alloy and a Sn—Pb alloy.

### REFERENCE NUMERALS

100 cell module
10 upper glass plate
20 front adhesive layer
30 cell array
31 cell
31A first cell
31B second cell
311 cell substrate
312 secondary grid line
312A front secondary grid line
312B back secondary grid line
3121 edge secondary grid line
3122 middle secondary grid line
3123 welding portion
313 back electric field
314 back electrode
32 conductive wire
32A front conductive wire
32B back conductive wire
321 metal wire body
322 welding layer
33 short grid line
40 back adhesive layer
50 water vapor insulation back plate
51 reflective coating
60 U-shape frame
70 junction box
80 mounting block

### DETAILED DESCRIPTION

Embodiments of the present disclosure will be described in detail and examples of the embodiments will be illustrated in the drawings, where same or similar reference numerals are used to indicate same or similar members or members with same or similar functions. The embodiments described herein with reference to the drawings are explanatory, which are used to illustrate the present disclosure, but shall not be construed to limit the present disclosure.

Part of technical terms in the present disclosure will be elaborated herein for clarity and convenience of description.

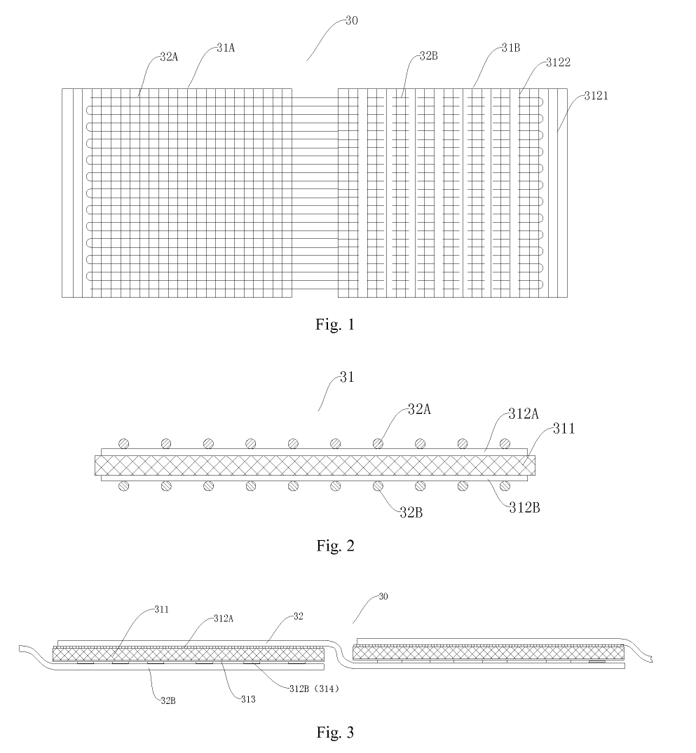

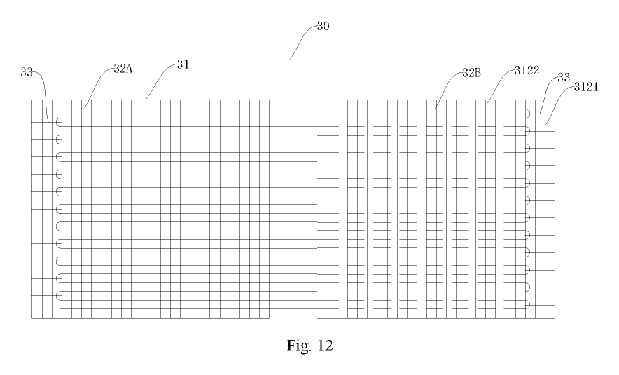

According to one embodiment of the present disclosure, referring to FIGS. 1-15, a cell 31 includes a cell substrate 311, secondary grid lines 312 disposed on a front surface (the surface on which light is incident) of the cell substrate 311, a back electric field 313 disposed on a back surface of the cell substrate 311, and back electrodes 314 disposed on the back electric field 313. Thus, the secondary grid lines 312 can be called the secondary grid lines 312 of the cell 31, the back electric field 313 called the back electric field 313 of the cell 31, and the back electrodes 314 called the back electrodes 314 of the cell 31.

The cell substrate 311 can be an intermediate product obtained by subjecting, for example, a silicon chip to processes of felting, diffusing, edge etching and silicon nitride layer depositing. However, it shall be understood that the cell substrate 311 in the present disclosure is not limited to be formed by the silicon chip, but includes a thin-film solar cell substrate or any other suitable solar cell substrate 311.

In other words, the cell 31 includes a silicon chip, some processing layers on a surface of the silicon chip, secondary grid lines on a shiny surface, and a back electric field 313 and back electrodes 314 on a shady surface, or includes other equivalent solar cells of other types without any front electrode, for instance, various film cells—a-Si film cell, CdTe solar cell, CIGS solar cell, GaAs solar cell, Nano-TiO₂ dye-sensitized solar cell (DSSC) etc.

A cell unit includes a cell 31 and conductive wires 32 constituted by a metal wire S.

A solar cell array 30 includes a plurality of cells 31 and conductive wires 32 which connect adjacent cells 31 and are constituted by the metal wire S. In other words, the solar cell array 30 is formed of a plurality of cells 31 connected by the conductive wires 32.

In the solar cell array 30, the metal wire S constitutes the conductive wires 32 of the cell unit, and extends between surfaces of the adjacent cells 31, which shall be understood in a broad sense that the metal wire S may extend between front surfaces of the adjacent cells 31, or may extend between a front surface of a first cell 31 and a back surface of a second cell 31 adjacent to the first cell 31. When the metal wire S extends between the front surface of the first cell 31 and the back surface of the second cell 31 adjacent to the first cell 31, the conductive wires 32 may include front conductive wires 32A extending on the front surface of the cell 31 and electrically connected with the secondary grid lines 312 of the cell 31, and back conductive wires 32B extending on the back surface of the cell 31 and electrically connected with the back electrodes 314 of the cell 31. Part of the metal wire S between the adjacent cells 31 can be called connection conductive wires.

In the present disclosure, descriptive terms, such as the cell substrate 311, the cell 31, the cell unit, the cell array 30 and the solar cell module are used only for the convenience of description, and shall not be construed to limit the present disclosure.

All the ranges disclosed in the present disclosure include endpoints, and can be individual or combined. It shall be understood that the endpoints and any value of the ranges are not limited to an accurate range or value, but also include values proximate the ranges or values.

In the present disclosure, the orientation terms such as “upper” and “lower” usually refer to the orientation “upper” or “lower” as shown in the drawings under discussion, unless specified otherwise; “front surface” refers to a surface of the solar cell module facing the light in practical disclosure, i.e. a shiny surface, while “back surface” refers to a surface of the solar cell module back to the light in practical disclosure.

In the following, the solar cell module 100 according to the embodiments of the present disclosure will be described with respect to the drawings.

As shown in FIG. 1 to FIG. 13, the solar cell module according to the embodiments of the present disclosure includes an upper glass plate 10, a front adhesive layer 20, a solar cell array 30, a back adhesive layer 40 and a water vapor insulation back plate 50 superposed in sequence; the water vapor insulation back plate 50 has a water vapor transmission rate (WVTR) of less than or equal to 0.1 mg/m²/day, preferably the water transmission rate being 0 and the air transmission rate being 0; the solar cell array 30 includes a plurality of cells 31 and conductive wires 32, adjacent cells 31 being connected by the conductive wires 32; the cells 31 are provided with secondary grid lines 312 on front surfaces thereof, the conductive wires 32 being welded with the secondary grid lines 312 by a welding layer with an alloy that contains Sn and Bi.

In other words, the solar cell module according to the embodiments of the present disclosure includes the upper glass plate 10, the front adhesive layer 20, the solar cell array 30, the back adhesive layer 40 and the water vapor insulation back plate 50 sequentially from up to down. The solar cell array consists of at least two cells 31, and adjacent two cells 31 are connected by a plurality of conductive wires 32. The conductive wires 32 are welded with the secondary grid lines 312 on the front surface of the cell 31 by the welding layer which is an alloy mainly containing Sn and Bi.

The conductive wires 32 are welded with the secondary grid lines 312, and will not drift or be insufficiently welded in the solar cell module, and hence obtain relatively high photoelectric conversion efficiency.

In the solar cell module according to the embodiments of the present disclosure, the water vapor insulation back plate 50 may be a glass or metal plate, in which the metal plate may be an aluminum plate.

It shall be noted that the present disclosure adopts upper and lower layers of closed glass and water vapor insulation back plates, to prevent moisture and corrosive gas from entering the interior. The welding layer for welding the conductive wires 32 and the secondary grid lines 312 employs an alloy with a low melting point and containing Sn and Bi, whose corrosion resistance is poorer than Sn on the surface of the welding strip. Under normal packaging conditions, the alloy may discolor and turns into black due to oxidation, which will affect the service life of the module. The present disclosure has a completely sealed structure, which can prevent the Sn—Bi alloy from color changing, lower corrosion of the cell array 30, effectively protect the cell array 30, reduce the corrosion of the module and prolong the service life of the module.

Therefore, in the solar cell module 100 according to the embodiments of the present disclosure, the secondary grid lines 312 and the conductive wires 32 on the cell 31 are connected by the welding layer with the alloy containing Sn and Bi, so as to improve the effect of connecting the conductive wires 32 and the cell 31, and to guarantee the photoelectric conversion efficiency. The upper glass plate 10, the front adhesive layer 20, the back adhesive layer 40 and the water vapor insulation back plate 50 may seal the welding layer effectively to protect the cell array, so as to slow down the corrosion of the solar cell module and to prolong the service life.

According to an embodiment of the present disclosure, the solar cell array 30 includes a plurality of cells 31, and the adjacent cells 31 are connected by the metal wire which extends reciprocally between a surface of a first cell 31 and a surface of a second cell 31 adjacent to the first cell 31, so as to form a plurality of conductive wires 32. The secondary grid lines 312 are disposed on the front surface of the cell 31, and the conductive wires 32 are welded with the secondary grid lines 312.

A cell unit is formed by the cell 31 and the conductive wires 32 constituted by the metal wire S which extends on the surface of the cell 31. In other words, the solar cell array 30 according to the embodiments of the present disclosure are formed with a plurality of cell units; the conductive wires 32 of the plurality of cells are formed by the metal wire S which extends reciprocally between the surfaces of the cells 31.

It shall be understood that the term “extending reciprocally” in the disclosure can be called “winding” which refers to that the metal wire S extends between the surfaces of the cells 31 along a reciprocal route. For example, referring to FIG. 1, in some circumstances, the metal wire extends between the surfaces of the cells 31 in the same plane, such as either between the front surfaces or between the bottom surfaces of the cells, to form a serpentine pattern. In some other circumstances, the metal wire S extends between the surfaces of the cells 31 in multiple planes, such as between both the front surface of a cell and the bottom surface of an adjacent cell, to form a serpentine pattern. In yet other circumstances, the metal wire S extends between the surfaces of the cells 31 both in the same plane and in multiple planes, such as sometimes between either the front surfaces or the bottom surfaces of some adjacent cells, and at other times between both the front surface of a certain cell and the bottom surface of an adjacent cell, to form a serpentine pattern. The plurality of conductive wires equals two or more passes of the serpentine shaped pattern. Preferably, two or more passes of the serpentine shaped pattern on the same plane are substantially parallel to each other. More preferably, all the passes of the serpentine shaped pattern on the same plane are substantially parallel to each other.

In the present disclosure, it shall be understood in a broad sense that “the metal wire S extends reciprocally between surfaces of the cells 31. For example, the metal wire S may extend reciprocally between a front surface of a first cell 31 and a back surface of a second cell 31 adjacent to the first cell 31; the metal wire S may extend from a surface of the first cell 31 through surfaces of a predetermined number of middle cells 31 to a surface of the last cell 31, and then extends back from the surface of the last cell 31 through the surfaces of a predetermined number of middle cells 31 to the surface of the first cell 31, extending reciprocally like this.

In addition, when the cells 31 are connected in parallel by the metal wire S, the metal wire S can extend on front surfaces of the cells, such that the metal wire S constitutes a front conductive wire 32A. Alternatively, a first metal wire S extends reciprocally between the front surfaces of the cells, and a second metal wire S extends reciprocally between the back surfaces of the cells, such that the first metal wire S constitutes a front conductive wire 32A, and the second metal wire S constitutes a back conductive wire 32B.

When the cells 31 are connected in series by the metal wire S, the metal wire S can extend reciprocally between a front surface of a first cell 31 and a back surface of a second cell 31 adjacent to the first cell 31, such that part of the metal wire S which extends on the front surface of the first cell 31 constitutes a front conductive wire 32A, and part thereof which extends on the back surface of the second cell 31 constitutes a back conductive wire 32B. In the present disclosure, unless specified otherwise, the conductive wire 32 can be understood as the front conductive wire 32A, the back conductive wire 32B, or the combination thereof.

The term “extending reciprocally” can be understood as that the metal wire S extends reciprocally once to form two conductive wires 32, and two conductive wires 32 are formed by winding one metal wire S, for example, two adjacent conductive wires constituting a U-shape structure or a V-shape structure, yet the present disclosure is not limited to the above.

In the solar cell array 30 according to the embodiments of the present disclosure, a plurality of conductive wires 32 of the cells are constituted by the metal wire S which extends reciprocally; and the adjacent cells 31 are connected by the conductive wires 32. Hence, the conductive wires 32 of the cells are not necessarily made of expensive silver paste, and can be manufactured in a simple manner without using a solder strip to connect the cells. It is easy and convenient to connect the metal wire S with the secondary grid line and the back electrode, so that the cost of the cells is reduced considerably.

Moreover, since the conductive wires 32 are constituted by the metal wire S which extends reciprocally, the width of the conductive wires 32 (i.e. the width of projection of the metal wire on the cell) may be decreased, thereby decreasing the shading area of the conductive wires 32. Further, the number of the conductive wires 32 can be adjusted easily, and thus the resistance of the conductive wires 32 is reduced, compared with the conductive wires made of the silver paste, and the efficiency of photoelectric conversion is improved. Since the metal wire S extends reciprocally to form the conductive wires, when the cell array 30 is used to manufacture the solar cell module 100, the metal wire S will not tend to shift, i.e. the metal wire is not easy to “drift”, which will not affect but further improve the photoelectric conversion efficiency.

In the embodiments of the present disclosure, secondary grid lines 312 and short grid lines 33 are disposed on a front surface of the cell 31; the secondary grid line 312 includes middle secondary grid lines 3122 intersected with the conductive wires 32 and edge secondary grid lines 3121 non-intersected with the conductive wires 32; the short grid lines 33 are connected with the edge secondary grid lines 3121, and are connected with the conductive wires 32 or at least one middle secondary grid line 3122.

The present disclosure relates to the solar cells connected by the conductive wires 32. The short grid lines 33 are disposed on the front surface of the cell 31 to solve the accuracy problem of connection between the conductive wires 32 and the cell 31, to avoid current loss. The process is simple and easy to realize, and can lower the cost considerably.

The secondary grid lines 312 located at a side surface of the cell substrate 311 include two parts—one part of the secondary grid lines 312 intersected with the conductive wires 32 and located in a middle position of the cell substrate 311 to form middle secondary grid lines 3122; the other part of the secondary grid lines 312 non-intersected with the conductive wires 32 and located at an edge of one side away from the conductive wires 32 to form edge secondary grid lines 3121.

The edge secondary grid lines 3121 are provided with short grid lines 33 connected with the conductive wires 32 or at least one middle secondary grid line 3122. In specific embodiments, the short grid lines 33 are located at the edges of the cell 31 where the conductive wires 32 cannot reach when being winded, so as to avoid current loss.

Alternatively, the metal wire breaks off at a turn after being connected with the cells 31.

Preferably, the short grid lines 33 are connected with the edge secondary grid line 3121 closest to the middle secondary grid lines 3122.

In some other specific embodiments of the present disclosure, the short grid lines 33 are connected with the conductive wires 32. Preferably, the short grid lines 33 and the metal wire at the front surface of the cell 31 are connected at a turn formed by reciprocal extension. An extra welding point can be added to decrease the probability of breaking the welding portion at the edges, and to further enhance the binding force of the metal wire and the cell. The connection with at the turn herein can be understood that the short grid lines 33 have intersection points with the turns, i.e. the short grid lines 33 do not terminate at the turns.

According to an embodiment of the present disclosure, the short grid lines 33 are perpendicular to the secondary grid lines 312. The short grid lines 33 are, preferably, electrically connected with bended parts (ends proximate to the edges) of the conductive wires 32 on the shiny surface of the cell 31. More preferably, at least one short grid line 33 is disposed corresponding with each bended part.

Since the distance between the bended parts of the conductive wires 32 and the edges of the cell 31 is usually short, the short grid lines 33 have a length of 1 to 10 mm, preferably 2.4 to 7 mm, a width of 0.05 to 0.5 mm, and a thickness of 0.01 to 0.02 mm. There are 3 to 40, preferably 6 to 20 short grid lines.

The short grid lines 33 can be disposed in the same manner as the secondary grid lines 312 on the shiny surface of the cell 31. For example, the short grid lines 33 can be printed along with the secondary grid lines 312 by silk-screen printing at the same screen plate (which can be made of silver paste) as the front secondary grid lines 3121.

Alternatively, the metal wire breaks off at a turn after being connected with the cell 31. The metal wire breaks off at the turn after being welded with the cell 31 to form multiple independent conductive wires 32.

The metal wire breaks off at the turn after being welded with the cell 31 to separate the multiple conductive wires 32, which can decrease the stress between the cells and peeling strength at the joints of the metal wire and the cell, and further improve the photoelectric conversion efficiency of the solar cell array 30.

Preferably, based on the total weight of the alloy, there are 15 to 60 weight percent of Bi, 30 to 75 weight percent of Sn, 0 to 20 weight percent of Cu, 0 to 40 weight percent of In, 0 to 3 weight percent of Ag, 0 to 20 weight percent of Sb, 0 to 10 weight percent of Pb, and 0 to 20 weight percent of Zn.

Further, the alloy can be at least one selected from 50% Sn-48% Bi-1.5% Ag-0.5% Cu, 58% Bi-42% Sn, and 65% Sn-20% Bi-10% Pb-5% Zn.

It can be appreciated to those skilled in the art that the Sn—Bi alloy (represented by line a in FIG. 15) is less easily oxidized than the Sn—Pb alloy (represented by line b in FIG. 15) under the same conditions. That is, the Sn—Bi alloy is more stable, and the Sn—Bi alloy has a lower water vapor transmission rate than the Sn—Pb alloy. Specifically in the solar cell according to the present disclosure, the Sn—Pb alloy is commonly used for welding in the art, but it is possible to employ the Sn—Bi alloy with higher stability for welding. Theoretically speaking, the back plate used in welding by the Sn—Pb alloy can fully satisfy the anti-oxidation requirement for the Sn—Bi alloy used in welding.

However, after a long-term research, the inventor of the present disclosure finds that the oxidation rate of the Sn—Bi alloy is higher than that of the Sn—Pb alloy in a humid environment. Hence, the inventor conducts an intensive study on the oxidation rate of the Sn—Bi alloy and the moisture transmission performance of the back plate, and it turns out that when the water vapor transmission rate of the back plate is larger than 0.1 mg/m²/day, the oxidation rate of the Sn—Bi alloy is sharply increased with the increase of the water vapor transmission rate; when the water vapor transmission rate of the back plate is less than or equal to 0.1 mg/m²/day, the oxidation rate of the Sn—Bi alloy does not change considerably as the water vapor transmission rate varies.

In order to solve the problem that the Sn—Bi alloy is easy to be oxidized, the present disclosure adopts upper and lower layers of closed glass and water vapor insulation back plates which have a water vapor transmission rate lower than 0.1 mg/m²/day, so as to avoid of oxidation of the Sn—Bi alloy material, to prevent moisture and corrosive gas from entering the interior of the solar cells, and thus to prevent the Sn—Bi alloy from color change and turning black due to oxidation under normal packaging conditions. Consequently, the Sn—Bi alloy can be protected effectively; the corrosion of the cell array 30 is reduced to effectively protect the cell array 30; the corrosion of the module is slowed to prolong the service life of the module.

Specifically, according to a preferable embodiment of the present disclosure, the secondary grid lines 312 and the conductive wires 32 are connected by a welding layer disposed on the secondary grid lines 312 or coating the metal wire. Alternatively, a welding layer is disposed at a position where the conductive wires 32 are in contact with the secondary grid lines 312 and/or the back electrodes 314 of the cell 31. More preferably, the welding layer is disposed at the positions where the conductive wires 32 are in contact with the secondary grid lines 312 of the cell 31 and in contact with the back electrodes 314 thereof respectively. The welding layer can be only applied to the secondary grid lines 312 and back electrodes 314, or can also be applied to the conductive wires 32.

In the cell array 30, the ratio of the thickness of the welding layer and the diameter of the conductive wire (including front conductive wire 32A and back conductive wire 32B) is (0.02-0.5): 1.

In the present disclosure, when there is a welding layer disposed at a position where the conductive wires 32 (including front conductive wire 32A and back conductive wire 32B) are in contact with the secondary grid lines 312 and/or the back electrodes 314 of the cell 31, the conductive wires 32 can be a metal wire. The metal wire may be conventional in the art, for example, a copper wire.

In an embodiment, the conductive wires (including the front conductive wires 32A and back conductive wires 32B) include a metal wire and an alloy layer with a low melting point coating the metal wire. The alloy layer may coat the metal wire completely or partially. When the alloy layer coats the metal wire partially, the alloy layer is, preferably, formed at a position where the alloy layer is welded with the secondary grid lines 312 and/or the back electrodes 314 of the cell 31. When the alloy layer coats the metal wire completely, the alloy layer can coat the periphery of the metal wire in a circular manner. The thickness of the alloy layer can fall into a relatively wide range. Preferably, the alloy layer has a thickness of 1 to 100 μm, more preferably, 1 to 30 μm. The alloy for forming the alloy layer with a low melting point may be a conventional alloy with a low melting point which can be 100 to 200° C. Preferably, the alloy is Bi—Sn—Pb alloy, for example, containing 40 weight percent of Sn, 55 weight percent of Bi, and 5 weight percent of Pb (i.e. Sn40%-Bi55%-Pb5%). The thickness of the alloy layer with the low melting point can be 0.001 to 0.06 mm. The conductive wire 32 may have a cross section of 0.01 to 0.5 mm². The metal wire can be conventional in the art, for example, a copper wire.

In the cell array 30, the cell 31 can be a conventional cell 31 in the art, for example, a polycrystalline silicon cell 31. The secondary grid lines 312 on the shiny surface of the cell 31 can be Ag, Cu, Sn, and tin alloy. The secondary grid line 312 has a width of 40 to 80 m and a thickness of 5 to 20 μm; there are 50 to 120 secondary grid lines, a distance between adjacent secondary grid lines ranging from 0.5 to 3 mm. The back electrodes 314 on the back surface of the cell 31 can be made of Ag, Cu, Sn and tin alloys. The back electrodes 314 are usually in a ribbon pattern, and have a width of 1 to 4 mm, and a thickness of 5 to 20 m.

In the following, the solar cell array 30 according to specific embodiments of the present disclosure will be described with reference to the drawings.

The solar cell array 30 according to a specific embodiment of the present disclosure is illustrated with reference to FIG. 1 to FIG. 3.

In the embodiment shown in FIG. 1 to FIG. 3, two cells in the solar cell array 30 are shown. In other words, it shows two cells 31 connected with each other via the conductive wire 32 constituted by the metal wire S.

It can be understood that the cell 31 includes a cell substrate 311, a secondary grid line 312 (a front secondary grid line 312A) disposed on a front surface of the cell substrate 311, a back electric field 313 disposed on a back surface of the cell substrate 311, and a back electrode 314 disposed on the back electric field 313. In the present disclosure, it can be understood that the back electrode 314 may be a back electrode of a traditional cell, for example, printed by the silver paste, or may be a back secondary grid line 312B similar to the secondary grid line on the front surface of the cell substrate, or may be multiple discrete welding portions, unless specified otherwise. The secondary grid line refers to the secondary grid line 312 on the front surface of the cell substrate 311, unless specified otherwise.

As shown in FIG. 1 to FIG. 3, the solar cell array in the embodiment includes two cells 31A, 31B (called a first cell 31A and a second cell 31B respectively for convenience of description). The metal wire S extends reciprocally between the front surface of the first cell 31A (a shiny surface, i.e. an upper surface in FIG. 2) and the back surface of the second cell 31B, such that the metal wire S constitutes a front conductive wire of the first cell 31A and a back conductive wire of the second cell 31B. The metal wire S is electrically connected with the secondary grid line of the first cell 31A (for example, being welded or bounded by a conductive adhesive), and electrically connected with the back electrode of the second cell 31B.

In an embodiment of the present disclosure, back electrodes 314 are disposed on the back surface of the cell substrate 311, and the metal wire is welded with the back electrodes 314.

That's to say, in the embodiment, front secondary grid lines 312A are disposed on the front surface of the cell substrate 311 whose back surface is provided with the back electrodes 314. The conductive wires 32 are located at the front surface of the cell substrates 311, and welded with the front secondary grid lines 312A. When located at the back surface of the cell substrates 311, the conductive wires 32 are welded with the back electrodes 314 on the back surface of the cell substrate 311.

In some embodiments, the metal wire extends reciprocally between the first cell 31A and the second cell 31B for 10 to 60 times. Preferably, as shown in FIG. 1, the metal wire extends reciprocally for 12 times to form 24 conductive wires, and there is only one metal wire. In other words, a single metal wire extends reciprocally for 12 times to form 24 conductive wires, and the distance of the adjacent conductive wires can range from 2.5 mm to 15 mm. In this embodiment, the number of the conductive wires is increased, compared with the traditional cell, such that the distance between the secondary grid line and the conductive wire which the current runs through is decreased, so as to reduce the resistance and improve the photoelectric conversion efficiency. In the embodiment shown in FIG. 1, the adjacent conductive wires form a U-shape structure, for convenience of winding the metal wire. Alternatively, the present disclosure is not limited to the above. For example, the adjacent conductive wires form a V-shape structure.

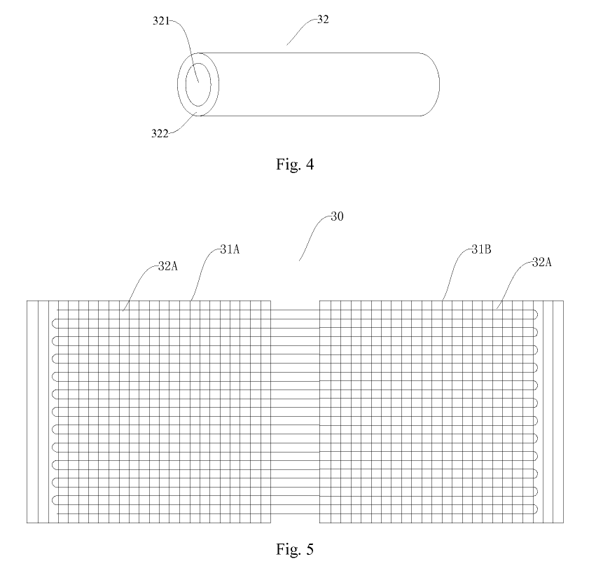

More preferably, as shown in FIG. 4, the metal wire S includes a metal wire body 321 and a welding layer 322 coating the outer surface of the metal wire body. The metal wire is welded with the secondary grid lines and/or the back electrodes by the welding layer, such that it is convenient to electrically connect the metal with the secondary grid lines and/or the back electrodes, and to avoid drifting of the metal wire in the connection process so as to guarantee the photoelectric conversion efficiency. Of course, the electrical connection of the metal with the cell substrate can be conducted during or before the laminating process of the solar cell module, and preference is given to the latter.

It shall be noted that in the present disclosure, the metal wire S refers to a metal wire for extending reciprocally on the cells 31 to form the conductive wires 32; and the conductive wires 32 include a metal wire body 321 and a welding layer 322 coating the metal wire body 321, i.e. the metal wire S consists of the metal wire body 321 and the welding layer 322 coating the metal wire body 321. In the embodiments of the present disclosure, unless specified otherwise, the metal wire represents the metal wire S which extends reciprocally on the cells to form the conductive wires 32.

In some embodiments, preferably, the metal wire body 321 is a copper wire. Of course, the metal wire S can be a copper wire, too. In other words, the metal wire does not include the welding layer 322, but the present disclosure does not limited thereto. For example, the metal wire body 321 can be an aluminum wire. Preferably, the metal wire S has a circular cross section, such that more sunlight can reach the cell substrate to further improve the photoelectric conversion efficiency.

In some embodiments, preferably, before the metal wire contact the cells, the metal wire extends under a strain, i.e. straightening the metal wire. After the metal wire is connected with the secondary grid lines and the back electrodes of the cell, the strain of the metal wire can be released, so as to further avoid the drifting of the conductive wires when the solar cell module is manufactured, and to guarantee the photoelectric conversion efficiency.

FIG. 5 is a schematic diagram of a solar cell array according to another embodiment of the present disclosure. As shown in FIG. 5, the metal wire extends reciprocally between the front surface of the first cell 31A and the front surface of the second cell 31B, such that the metal wire constitutes a front conductive wire of the first cell 31A and a front conductive wire of the second cell 31B. In such a way, the first cell 31A and the second cell are connected in parallel. Of course, it can be understood that preferably the back electrode of the first cell 31A and the back electrode of the second cell 31B can be connected via a back conductive wire constituted by another metal wire which extends reciprocally. Alternatively, the back electrode of the first cell 31A and the back electrode of the second cell 31B can be connected in a traditional manner.

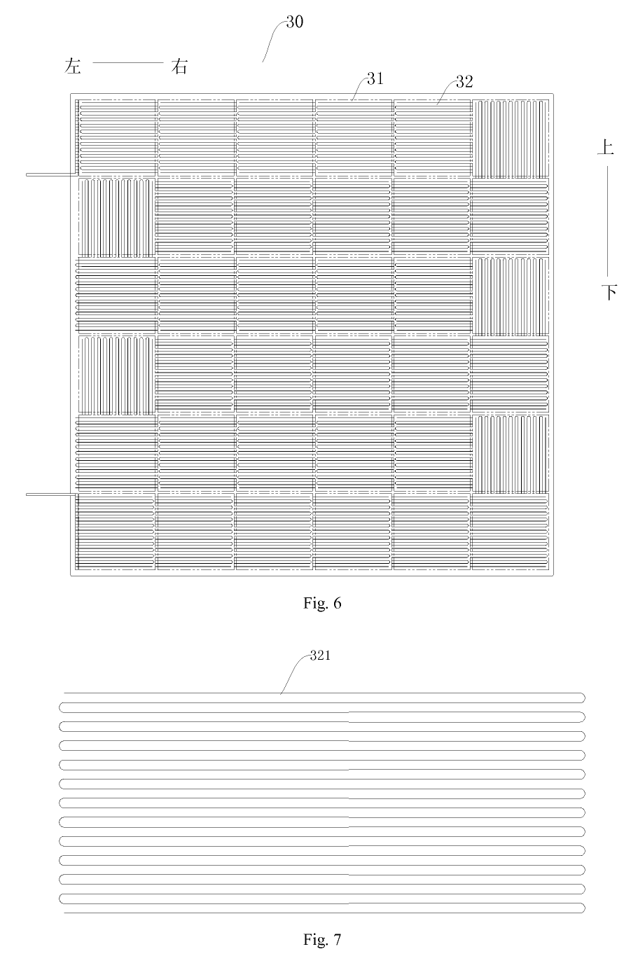

The solar cell array 30 according to another embodiment of the present disclosure is illustrated with reference to FIG. 6.

The solar cell array 30 according to the embodiment of the present disclosure comprises n×m cells 31. In other words, a plurality of cells 31 are arranged in an n×m matrix form, n representing a column, and m representing a row. More specifically, in the embodiment, 36 cells 31 are arranges into six columns and six rows, i.e. n=m=6. It can be understood that the present disclosure is not limited thereto. For example, the column number and the row number can be different. For convenience of description, in FIG. 6, in a direction from left to right, the cells 31 in one row are called a first cell 31, a second cell 31, a third cell 31, a fourth cell 31, a fifth cell 31, and a sixth cell 31 sequentially; in a direction from up to down, the columns of the cells 31 are called a first column of cells 31, a second column of cells 31, a third column of cells 31, a fourth column of cells 31, a fifth column of cells 31, and a sixth column of cells 31 sequentially.

In a row of the cells 31, the metal wire extends reciprocally between a surface of a first cell 31 and a surface of a second cell 31 adjacent to the first cell 31; in two adjacent rows of cells 31, the metal wire extends reciprocally between a surface of a cell 31 in a a^{th} row and a surface of a cell in a (a+1)^{th} row, and m−1≧a≧1.

As shown in FIG. 6, in a specific example, in a row of the cells 31, the metal wire extends reciprocally between a front surface of a first cell 31 and a back surface of a second cell 31 adjacent to the first cell 31, so as to connect the cells in one row in series. In two adjacent rows of cells 31, the metal wire extends reciprocally between a front surface of a cell 31 at an end of the a^{th} row and a back surface of a cell 31 at an end of the (a+1)^{th} row, to connect the two adjacent rows of cells 31 in series.

More preferably, in the two adjacent rows of cells 31, the metal wire extends reciprocally between the surface of the cell 31 at an end of the a^{th} row and the surface of the cell 31 at an end of the (a+1)^{th} row, the end of the a^{th} row and the end of the (a+1)^{th} row located at the same side of the matrix form, as shown in FIG. 6, located at the right side thereof.

More specifically, in the embodiment as shown in FIG. 6, in the first row, a first metal wire extends reciprocally between a front surface of a first cell 31 and a back surface of the second cell 31; a second metal wire extends reciprocally between a front surface of the second cell 31 and a back surface of a third cell 31; a third metal wire extends reciprocally between a front surface of the third cell 31 and a back surface of a fourth cell 31; a fourth metal wire extends reciprocally between a front surface of the fourth cell 31 and a back surface of a fifth cell 31; a fifth metal wire extends reciprocally between a front surface of the fifth cell 31 and a back surface of a sixth cell 31. In such a way, the adjacent cells 31 in the first row are connected in series by corresponding metal wires.

A sixth metal wire extends reciprocally between a front surface of the sixth cell 31 in the first row and a back surface of a sixth cell 31 in the second row, such that the first row and the second row are connected in series. A seventh metal wire extends reciprocally between a front surface of the sixth cell 31 in the second row and a back surface of a fifth cell 31 in the second row; a eighth metal wire extends reciprocally between a front surface of the fifth cell 31 in the second row and a back surface of a fourth cell 31 in the second row, until a eleventh metal wire extends reciprocally between a front surface of a second cell 31 in the second row and a back surface of a first cell 31 in the second row, and then a twelfth metal wire extends reciprocally between a front surface of the first cell 31 in the second row and a back surface of a first cell 31 in the third row, such that the second row and the third row are connected in series. Sequentially, the third row and the fourth row are connected in series, the fourth row and the fifth row connected in series, the fifth row and the sixth row connected in series, such that the cell array 30 is manufacture. In this embodiment, a bus bar is disposed at the left side of the first cell 31 in the first row and the left side of the first cell 31 in the sixth row respectively; a first bus bar is connected with a conductive wire extending from the left side of the first cell 31 in the first row, and a second bus bar is connected with a conductive wire extending from the left side of the first cell 31 in the sixth row.

As said above, the cells in the embodiments of the present disclosure are connected in series by the conductive wires—the first row, the second row, the third row, the fourth row, the fifth row and the sixth row are connected in series by the conductive wires. As shown in the figures, alternatively, the second and third row, and the fourth and fifth rows can be connected in parallel with a diode respectively to avoid light spot effect. The diode can be connected in a manner commonly known to those skilled in the art, for example, by a bus bar.

However, the present disclosure is not limited to the above. For example, the first and second rows can be connected in series, the third and fourth rows connected in series, the fifth and sixth rows connected in series, and meanwhile the second and third rows are connected in parallel, the fourth and fifth connected in parallel. In such a case, a bus bar can be disposed at the left or right side of corresponding rows respectively.

Alternatively, the cells 31 in the same row can be connected in parallel. For example, a metal wire extends reciprocally from a front surface of a first cell 31 in a first row through the front surfaces of the cells 31 in the second row to the sixth row.

In an embodiment of the present disclosure, the secondary grid line 312 has a width of 40 to 80 μm and a thickness of 5 to 20 μm; there are 50 to 120 secondary grid lines, a distance between adjacent secondary grid lines ranging from 0.5 to 3 mm. The secondary grid lines 312 in this structure can be welded with the conductive wires 32 better to improve the photoelectric conversion efficiency.

Preferably, the front adhesive layer 20 and the back adhesive layer 40 are silica gel, which can convert the ultraviolet light absorbed by EVA ultraviolet absorbent to electric energy, compared with the traditional EVA encapsulation, to increase the output of the photovoltaic module. Moreover, the new-type packaging film is stable under UV irradiation, and has good weather resistance, such that it will not be degraded to produce acetic acid micro-molecules and erode the cell. In addition, the water vapor insulation back plate which has a water vapor transmission rate of less than or equal to 0.1 mg/m²/day is employed, and the secondary grid lines on the cells are connected with the conductive wires by the welding layer of the alloy containing Sn and Bi, which can effectively improve the effect of connecting the conductive wires and the cells, to guarantee the photoelectric conversion efficiency.

The silica gel used in the silicone membrane module has a thermoplastic film structure, which is solid at room temperature and is gradually softened as the temperature rises. The transparent liquid silica gel is two-component silica gel, in which the two components are mixed at a ratio of 1:1, and solidified by laminating at 70 to 130° C. into a thermoset transparent silica gel. The laminating temperature is low, which can save energy and prolong the service life of the laminator. The upper glass plate 10 and the back plate in the solar cell module of the present disclosure are made of the rigid glass which is easier to be coated and laminated than a conventional back plate of polymer materials. The temperature of the module in use may reach 80 to 100° C., at which temperature the thermoplastic film will be softened and thus has certain mobility. However, the thermoset film does not have the defect, and thus the module has better temperature resistance.

As shown in FIG. 10, further the water vapor insulation back plate 50 is coated with a white reflective coating 51 inside. In the present disclosure, the water vapor insulation back plate is coated with a white reflective coating 51 inside, such that the light which penetrates the gap of the cells 31 can be reflected to decrease packaging loss.

In the present disclosure, a glass or metal plate is used as the back plate, which has excellent corrosion resistance, weather resistance and abrasion resistance compared with conventional high-molecular plates. In such a case, the internal electronic elements are completely separated from the external environment, to prolong the service life of the module.

In a preferable embodiment, the upper glass plate 10 and the water vapor insulation back plate 50 are sealed by clamping a sealant of butyl rubber or polyisobutylene rubber at the peripheries thereof.

In the present disclosure, the butyl rubber or polyisobutylene rubber which has low moisture transmittance is used inside of the outermost periphery of the two layers of glass, to solve the problem that the edges of the original photovoltaic module exposes the packaging materials outsides. Moreover, the upper and lower layers of glass are bounded tightly, which can obstruct the moisture from the external environment, and prevent corrosive gas from penetrating into the module, so as to slow down the decay of the module and prolong the service life thereof.

Further preferably, the peripheries of the upper glass plate 10 and the water vapor insulation back plate 50 are fixed by silica gel or butyl rubber or double-sided sticky tape via a U-shape frame 60, and a sealant is filled between the peripheries of the upper glass plate 10 and the water vapor insulation back plate 50 and the U-shape frame 60.

In the present disclosure, the peripheries of the two layers of glass fix the U-shape frame by silica gel or butyl rubber or double-sided sticky tape. The frame is made of aluminum or high molecular materials. In such a case, the corners of the rigid glass tend to break under stress, and thus the safety is low and the risk in transporting and assembling is high. With protection of the U-shape rigid frame, the edges and corners of the double-glass module have higher impact resistance, and better sealing effect.

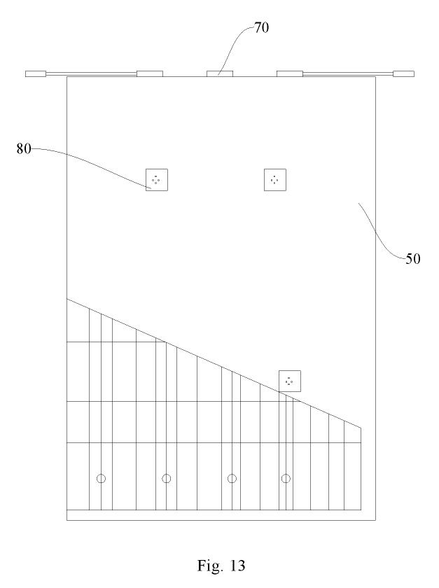

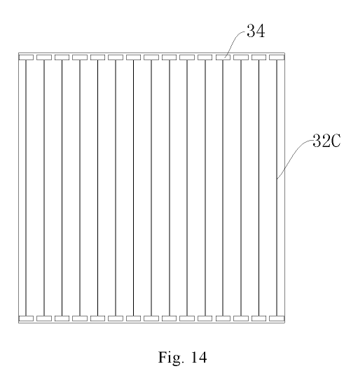

As shown in FIG. 13, the solar cell module according to the embodiments of the present disclosure further includes a junction box 70 disposed at the edge of the upper glass plate 10 and the water vapor insulation back plate 50.

In the present disclosure, the junction box 70 is disposed at the edge of the solar cell module instead of in the opening hole or groove at the back surface of the solar cell module, which can remain the entire structure of the back glass without forming any hard sport, so as to improve safety. In addition, the arrangement of the junction box 70 can, compared with the traditional module, reduce the number of the bus bars inside the solar cell module and the length of the external cable, which saves the cost, reduces the resistance and hence increases the power output.

In the process of manufacturing the solar cell module of the present disclosure, the conductive wires 32 can be first bounded or welded with the secondary grid lines 32 and back electrodes on the cell, and then they are superposed and laminated.

In a specific embodiment of the present disclosure, the solar cell module 100 includes an upper cover plate 10, a front adhesive layer 20, the cell array 30, a back adhesive layer 40 and a water vapor insulation back plate 50. The cell array 30 includes a plurality of cells 31, and adjacent cells 31 are connected by the plurality of conductive wires 32. The conductive wires 32 are constituted by the metal wire S which extends reciprocally between surfaces of adjacent cells. The conductive wires 32 are welded with the secondary grid lines. The front adhesive layer 20 contacts with the conductive wires 32 directly and fills between the adjacent conductive wires 32.

That's to say, the solar cell module 100 according to the present disclosure includes an upper cover plate 10, a front adhesive layer 20, the cell array 30, a back adhesive layer 40 and a back plate 50 superposed sequentially along a direction from up to down. The cell array 30 includes a plurality of cells 31 and conductive wires 32 for connecting the plurality of cells 31. The conductive wires are constituted by the metal wire S which extends reciprocally between surfaces of two adjacent cells 31.

The conductive wires 32 are electrically connected with the cells 31, in which the front adhesive layer 20 on the cells 31 contacts with the conductive wires 32 directly and fills between the adjacent conductive wires 32, such that the front adhesive layer 20 can fix the conductive wires 32, and separate the conductive wires 32 from air and moisture from the outside world, so as to prevent the conductive wires 32 from oxidation and to guarantee the photoelectric conversion efficiency.

Thus, in the solar cell module 100 according to embodiments of the present disclosure, the conductive wires 32 constituted by the metal wire S which extends reciprocally replace traditional primary grid lines and solder strips, so as to reduce the cost. The metal wire S extends reciprocally to decrease the number of free ends of the metal wire S and to save the space for arranging the metal wire S, i.e. without being limited by the space. The number of the conductive wires 32 constituted by the metal wire which extends reciprocally may be increased considerably, which is easy to manufacture, and thus is suitable for mass production. The front adhesive layer 20 contacts with the conductive wires 32 directly and fills between the adjacent conductive wires 32, which can effectively isolate the conductive wires from air and moisture to prevent the conductive wires 32 from oxidation to guarantee the photoelectric conversion efficiency.

In some specific embodiments of the present disclosure, the metal wire S extends reciprocally between a front surface of a first cell and a back surface of a second cell adjacent to the first cell; the front adhesive layer 20 contacts with the conductive wires on the front surface of the first cell 31 directly and fills between the adjacent conductive wires 32 on the front surface of the first cell 31; the back adhesive layer 40 contacts with the conductive wires 32 on the back surface of the second cell 31 directly and fills between the adjacent conductive wires 32 on the back surface of the second cell 31.

In other words, in the present disclosure, the two adjacent cells 31 are connected by the metal wire S. In the two adjacent cells 31, the front surface of the first cell 31 is connected with the metal wire S, and the back surface of the second cell 31 is connected with the metal wire S.

The front adhesive layer 20 on the first cell 31 whose front surface is connected with the metal wire S is in direct contact with the metal wire S on the front surface of the first cell 31 and fills between the adjacent conductive wires 32. The back adhesive layer 40 on the second cell 31 whose back surface is connected with the metal wire S is in direct contact with the metal wire S on the back surface of the second cell 31 and fills between the adjacent conductive wires 32 (as shown in FIG. 2).

Consequently, in the solar cell module 100 according to the present disclosure, not only the front adhesive layer 20 can separate the conductive wires 32 on the front surfaces of part of the cells 31 from the outside world, but also the back adhesive layer 40 can separate the conductive wires 32 on the back surfaces of part of the cells 31 from the outside world, so as to further guarantee the photoelectric conversion efficiency of the solar cell module 100.

In some specific embodiments of the present disclosure, for the normal cell with a dimension of 156 mm×156 mm, the solar cell module has a series resistance of 380 to 440 mΩ per 60 cells. The present disclosure is not limited to 60 cells, and there may be 30 cells, 72 cells, etc. When there are 72 cells, the series resistance of the solar cell module is 456 to 528 mΩ, and the electrical performance of the cells is better.

In some specific embodiments of the present disclosure, for the normal cell with a dimension of 156 mm×156 mm, the solar cell module has an open-circuit voltage of 37.5-38.5V per 60 cells. The present disclosure is not limited to 60 cells, and there may be 30 cells, 72 cells, etc. The short-circuit current is 8.9 to 9.4 A, and has nothing to do with the number of the cells.

In some specific embodiments of the present disclosure, the solar cell module has a fill factor of 0.79 to 0.82, which is independent from the dimension and number of the cells, and can affect the electrical performance of the cells.

In some specific embodiments of the present disclosure, for the normal cell with a dimension of 156 mm×156 mm, the solar cell module has a working voltage of 31.5-32V per 60 cells. The present disclosure is not limited to 60 cells, and there may be 30 cells, 72 cells, etc. The working current is 8.4 to 8.6 A, and has nothing to do with the number of the cells.

In some specific embodiments of the present disclosure, for the normal cell with a dimension of 156 mm×156 mm, the solar cell module has a conversion efficiency of 16.5-17.4%, and a power of 265-280 W per 60 cells.

A method for manufacturing the solar cell module according to the embodiments of the present disclosure will be illustrated in the following.

Specifically, the method according to the embodiments of the present disclosure includes the following steps: superposing an upper glass plate 10, a front adhesive layer 20, the cell array 30, a back adhesive layer 40 and a water vapor insulation back plate 50 in sequence, in which a front surface of a cell 31 faces the front adhesive layer 20, a back surface thereof facing the back adhesive layer 40, and laminating them to obtain the solar cell module 100, and in which the solar cell array 30 includes a plurality of cells 31 and conductive wires 32, and the adjacent cells are connected by the conductive wires. The cells 31 are provided with secondary grid lines 312 on front surfaces thereof, and the conductive wires 32 are welded with the secondary grid lines 312 by a welding layer with an alloy which contains Sn and Bi.

The front adhesive layer 20 and the back adhesive layer 40 are adhesive layers commonly used in the art. Preferably, the front adhesive layer 20 and the back adhesive layer 40 are thermosetting silica gel. In the present disclosure, the thermosetting silica gel may be obtained by using conventional products in the art or in a well-known preparation method.

The method according to the embodiments of the present disclosure includes the steps of preparing a solar array 30, superposing the upper cover plate 10, the front adhesive layer 20, the cell array 30, the back adhesive layer 40 and the water vapor insulation back plate 50 in sequence, and laminating them to obtain the solar cell module 100. It can be understood that the method further includes other steps, for example, sealing the gap between the upper cover plate 10 and the water vapor insulation back plate 50 by a sealant, and fixing the above components together by a U-shape frame, which are known to those skilled in the art, and thus will be not described in detail herein.

Specifically, the preparation of the solar array 30 includes a step of forming a plurality of conductive wires by a metal wire which extends reciprocally surfaces of cells 31 and is electrically connected with the surfaces of cells 31, such that the adjacent cells 31 are connected by the plurality of conductive wires to constitute a cell array 30.

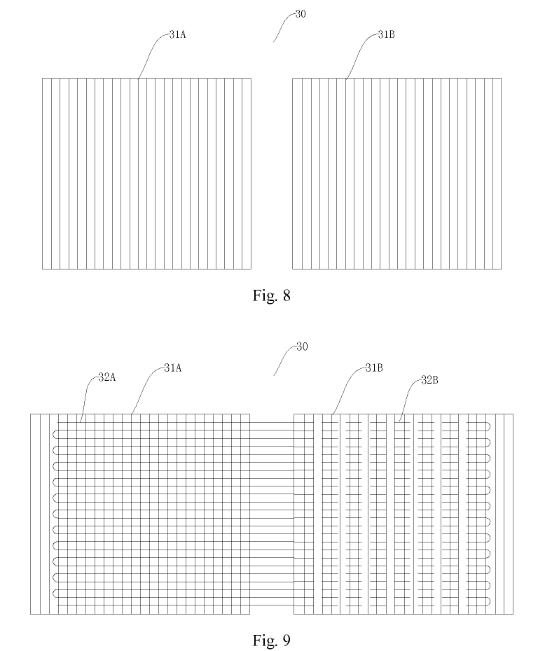

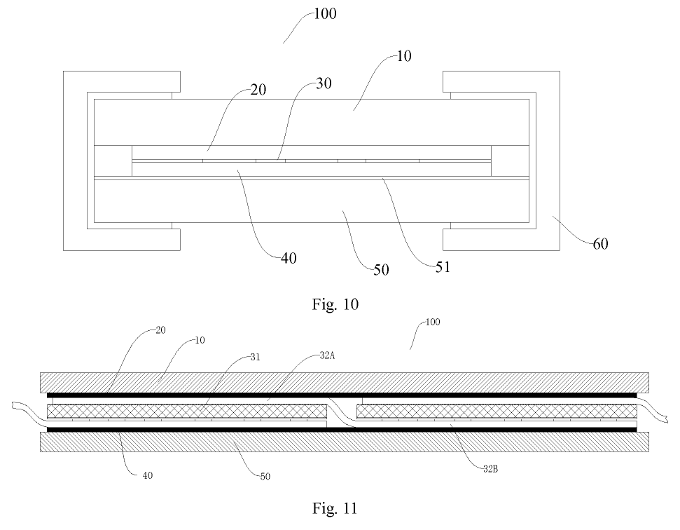

Specifically, as shown in FIG. 7, the metal wire extends reciprocally for 12 times under a strain. As shown in FIG. 8, a first cell 31A and a second cell 31B are prepared. As shown in FIG. 9, a front surface of the first cell 31A is connected with a metal wire, and a back surface of the second cell 31B is connected with the metal wire, such that the cell array 30 is formed. FIG. 9 shows two cells 31. When the cell array 30 has a plurality of cells 31, the metal wire which extends reciprocally connects the front surface of the first cell 31 and the back surface of the second cell 31 adjacent to the first cell 31, i.e. connecting a secondary grid line of the first cell 31 with a back electrode of the second cell 31 by the metal wire. The metal wire is strained by two clips at two ends of the wire and thus extends reciprocally.

In the embodiment shown in FIG. 9, the adjacent cells are connected in series. As said above, the adjacent cells can be connected in parallel by the metal wire based on practical requirements.

The cell array 30 obtained is superposed with the upper cover plate 10, the front adhesive layer 20, the back adhesive layer 40 and the lower glass or metal plate 50 in sequence, in which a front surface of the cell 31 faces the front adhesive layer 20, a back surface thereof facing the back adhesive layer 40, and laminating them to obtain the solar cell module 100. It can be understood that the metal wire can be welded with the cell 31 when or before they are laminated.

In the process of manufacturing the solar cell module according to the embodiments of the present disclosure, the metal wire extends reciprocally under a strain between a front surface of a first cell 31 and a back surface of a second cell 31 adjacent to the first cell 31. The conductive wires 32 include front conductive wires 32A connected with the secondary grid lines on the front surface of the cell 31 and back conductive wires 32B connected with the secondary grid lines on the back surface of the cell 31. The metal wire extends reciprocally for 10 to 60 times. The distance between two adjacent conductive wires ranges from 2.5 mm to 15 mm, and the two adjacent conductive wires form a U-shape structure or a V-shape structure.

Alternatively, there is a metal wire. The cells 31 are arranged in an n×m matrix form, n representing a column, and m representing a row. In a row of cells 31, the metal wire extends reciprocally between a surface of a first cell 31 and a surface of a second cell 31 adjacent to the first cell 31; in two adjacent rows of cells 31, the metal wire extends reciprocally between a surface of a cell 31 in a a^{th} row and a surface of a cell 31 in a (a+1)^{th} row, and m−1≧a≧1.

Preferably, in two adjacent rows of cells 31, the metal wire extends reciprocally between a surface of a cell 31 at an end of the a^{th} row and a surface of a cell 31 at an end of the (a+1)^{th} row, the end of the a^{th} row and the end of the (a+1)^{th} row located at the same side of the matrix form.

Further, in a row of cells 31, the metal wire extends reciprocally between a front surface of the first cell 31 and a back surface of the second cell 31 adjacent to the first cell 31; in two adjacent rows of cells 31, the metal wire extends reciprocally between a front surface of a cell 31 at the end of the a^{th} row and a back surface of a cell 31 at the end of the (a+1)^{th} row, to connect the two adjacent rows of cells 31 in series.

In some specific embodiments of the present disclosure, there is a metal wire extending reciprocally between adjacent cells 31 in a row; and there is a metal wire extending reciprocally between cells 31 in adjacent rows. The metal wire is a copper wire, and has a circular cross section.

In other words, the method for manufacturing the solar cell module according to the embodiments of the present disclosure includes two steps:

(1) arranging at least cells into a matrix form, in which the conductive wires extend reciprocally between a surface of a first cell 31 and a surface of a second cell 31 adjacent to the first cell 31 to form a folded shape, and the secondary grid lines on the shiny surface of the first cell 31 are welded with the conductive wires, and the back electrodes on the back surface of the second cell 31 are welded with the conductive wires;

(2) superposing a upper glass plate 10, a front adhesive layer 20, the cell array 30 obtained in step (1), a back adhesive layer 40 and a water vapor insulation back plate 50 sequentially from up to down, in which a front surface of a cell 31 faces the front adhesive layer 20, a back surface thereof facing the back adhesive layer 40, and laminating them.

In step (1), preferably, in two adjacent rows of the cells 31, the conductive wires extend from a surface of a cell 31 in a a^{th} row to a surface of a cell 31 in a (a+1)^{th} row; more preferably, the conductive wires extend from a front surface of a cell 31 at the end of the a^{th} row and a back surface of a cell 31 at the end of the (a+1)^{th} row.

In an embodiment, further preferably, in a row of the cells 31, the conductive wires extend from a shiny surface of a first cell 31 to a shady surface of a second cell 31 adjacent to the first cell 31; in two adjacent rows of cells 31, the conductive wires extend from a shiny surface of a cell 31 at the end of the a^{th} row to a back surface of a cell 31 proximate the end of the (a+1)^{th} row.

In step (1), the conductive wires are arranged in a winding way between the cells 31 in the same row, and/or the conductive wires are in a winding way between two adjacent rows of the cells 31. Most preferably, the conductive wires are arranged in a winding way both between the cells 31 in the same row and between two adjacent rows of the cells 31.

In the above method for manufacturing the solar cell module, the conductive wires, the secondary grid lines, the metal wire, the alloy layer with a low melting point, the adhesive layers, the upper glass plate and the water vapor insulation back plate are the same as the preceding description.

The laminating process can be conducted in a laminator, and include two stages, namely vacuuming at a low temperature and hot pressing.

In the above method for manufacturing the solar cell module, the process of welding can be a conventional welding way in the art. Preferably, the welding way is non-contact which refers to high-frequency welding or far infrared welding, so as to implement welding of the cell 31 with multiple conductive wires, avoid insufficient welding, and to prevent the conductive wires from drifting.

In some specific embodiments of the present disclosure, a mounting block 80 is bonded on the back surface of the water vapor insulation back plate 50, and is fixed on a frame, after the upper glass plate 10, the front adhesive layer 20, the cell array 30 and the back adhesive layer 40 and the water vapor insulation back 50 are superposed in sequence.

In the present disclosure, the solar cell module is mounted in a different way from the frame of the traditional module or the edges of the double-glass module which are clamped from both sides. In the present disclosure, the back surface of the module adopts four mounting blocks bounded with high intensity, and the mounting blocks are fixed on the frame by bolts. In such a case, the module is evenly stressed, which enhances the load-bearing ability in a more safe and reliable manner.

In the present disclosure, the solar cell array 30 is connected in a different way from the conventional modules. Instead, two cells without conductive wires are connected by a single fine copper wire coated with an alloy with a low melting point. It can be understood that the fine copper wire coated with the alloy with the low melting point replaces the conductive wires and the solder strip of the traditional silicon cell, and spares the bus bars at an end with no outgoing line. The fine copper wire coated with the alloy with the low melting point is called the conductive wire for the sake of convenience. The cell remains the traditional first step of front screen printing—manufacturing the bottom grid lines on the cell which we call fine grid lines as a rule. Then the conductive wires are bended in different ways into a plurality of grid lines perpendicular to the fine grid lines, to cover the fine grid lines and form a conductive crossed grid structure. Compared with the traditional technique of conductive wires, since the copper wire has a circular cross section, the module formed by the copper wire will have a smaller shady surface, which can reduce resistance loss and promote the total power of the module. Since 20 to 30 conductive wires are arranged intensively, there are many contacts between the conductive wires and the fine grid lines, to optimize the transmission route of electric current at the positions where the wafer cracks subtly or slightly, so as to reduce the loss due to the cracks. More significantly, the conductive wires are made from copper wires, so to decrease the consumption of silver materials.

### Example 1

Example 1 is used to illustrate the solar cell module 100 according to the present disclosure and the manufacturing method thereof.

(1) Manufacturing a Conductive Wire

A copper wire is attached to an alloy layer of 50% Sn-48% Bi-1.5% Ag-0.5% Cu (melting point: 160° C.), in which the copper wire has a cross section of 0.04 mm², and the alloy layer has a thickness of 16 μm, so as to obtain the conductive wire.

(2) Manufacturing a Solar Cell Module 100

A POE adhesive layer in 1630×980×0.5 mm are provided (melting point: 65° C.), and a glass plate in 1650×1000×3 mm and a polycrystalline silicon cell 31 in 156×156×0.21 mm are provided correspondingly. The cell 31 has 91 secondary grid lines (silver, 60 μm in width, 9 μm in thickness), each of which substantially runs through the cell 31 in a longitudinal direction, and the distance between the adjacent secondary grid lines is 1.7 mm. The cell 31 has five back electrodes (tin, 1.5 mm in width, 10 μm in thickness) on its back surface. Each back electrode substantially runs through the cell 31 in a longitudinal direction, and the distance between the adjacent back electrodes is 31 mm.

60 cells 31 are arranged in a matrix form (six rows and ten columns). In two adjacent cells 31 in a row, a metal wire extends reciprocally between a front surface of a first cell 31 and a back surface of a second cell 31 under a strain. For example, pins are disposed in two columns, and each pin in the same column is spaced apart from each other. In such a case, the metal wire extends reciprocally between the two columns of pins. Or the metal wire extends reciprocally under a strain from two clips at two ends thereof, so as to form 15 parallel conductive wires. The secondary grid lines of the first cell 31 are welded with the conductive wires and the back electrodes of the second cell 31 are welded with the conductive wires at a welding temperature of 180° C. The distance between parallel adjacent conductive wires is 9.9 mm. In this way, 10 cells are connected in series into a row, and 6 rows of the cells connected in series are connected in series into a cell array. The surfaces of the upper glass plate 10 and the lower glass plate (with a water vapor transmission rate of 0 mg/mm²*day) facing the cell 31 are coated with silica gel, and then butyl rubber sealing rubber strips are stuck around the silica gel. Then, the upper glass plate, multiple cells arranged in a matrix form and welded with the metal wire, the lower glass plate are superposed sequentially from up to down, in which the shiny surface of the cell 31 faces the front adhesive layer 20 in direct contact with the conductive wires; the shady surface of the cell 31 faces the back adhesive layer 40; and finally they are laminated in a laminator, in which the front adhesive layer 20 fills between adjacent conductive wires 32. In such way, a solar cell module is obtained.

### Example 2

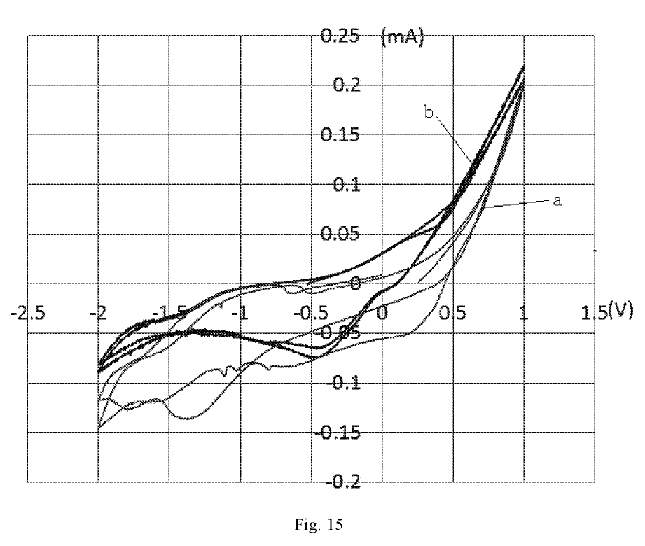

The difference between Example 2 and Example 1 lies in that the cells 31 are arranged in a matrix form, and in two adjacent cells, the fifteen parallel metal wires, by wiredrawing as shown in FIG. 14, are strained via the clips at the ends of each metal wire, and thus the cells are flattened at a strain of 2N of the clips. Each of the fifteen parallel metal wires is welded with secondary grid lines on a front surface of a first cell 31 respectively, and welded with back electrodes on a back surface of a second cell 31. The distance between the parallel adjacent conductive wires is 9.9 mm. In such a way, a solar cell module is obtained.

### Comparison Example 1

The differences between Comparison example 1 and Comparison example 1 lie in that the cells are arranged in a matrix form; 15 metal wires connected in series are pasted at a transparent adhesive layer, and the metal wires are attached to the solar cells. In two adjacent cells, the metal wire connects a front surface of a first cell and a back surface of a second cell. Then, an upper glass plate, an upper POE adhesive layer, and a first transparent adhesive layer, multiple cells arranged in a matrix form and welded with the metal wire, a second transparent adhesive layer, a lower POE adhesive layer and a lower glass plate are superposed sequentially from up to down. Thus, a solar cell module is obtained.

### Comparison Example 2

The difference between Comparison example 2 and Example 1 lies in that the back plate employs a PET plate instead of a glass plate, so as to obtain a solar cell module.

### Example 3

The solar cell module is manufactured according to the method in Example 1, but the difference compared with Example 1 lies in that 20 conductive wires are formed by reciprocal extension, and the distance between the parallel conductive wires is 7 mm. In such a way, a solar cell module is obtained.

### Example 4

The solar cell module is manufactured according to the method in Example 1, but the difference compared with Example 1 lies in that the alloy layer is Sn40%-Bi55%-Pb5% (melting point: 125° C.). In such a way, a solar cell module is obtained.

### Example 5

The solar cell module is manufactured according to the method in Example 1, but the difference compared with Example 1 lies in that the alloy layer is 58% Bi-42% Sn. In such a way, a solar cell module is obtained.

### Example 6

The solar cell module is manufactured according to the method in Example 1, but the difference compared with Example 1 lies in that the alloy layer is 65% Sn-20% Bi-10% Pb-5% Zn. In such a way, a solar cell module is obtained.

### Example 7

The solar cell module is manufactured according to the method in Example 3, but the difference compared with Example 3 lies in that the cell array is connected in such a manner that in two adjacent rows of cells, the conductive wires extend from a shiny surface of a cell at an end of the a^{th} row (a≧1) to form electrical connection with a back surface of a cell 31 at an adjacent end of the (a+1)^{th} row, so as to connect the two adjacent rows of cells. The conductive wires for connecting the two adjacent rows of cells 31 are arranged in perpendicular to the conductive wires for connecting the adjacent cells 31 in the two rows. In such a way, a solar cell module is obtained.

### Example 8

The solar cell module is manufactured according to the method in Example 1, but the difference compared with Example 1 lies in that the back plate is an aluminum plate with a water vapor transmission rate of 0 mg/mm²*day.

### Example 9

The solar cell module is manufactured according to the method in Example 1, but the difference compared with Example 1 lies in that the back plate is a semi-tempered glass having a thickness of 2.5 mm and a water vapor transmission rate of 0 mg/mm²*day.

### Example 10

The solar cell module is manufactured according to the method in Example 1, but the difference compared with Example 1 lies in that the back plate consists of two layers of TPT and a PIB rubber layer with a water vapor transmission rate of 0.1 mg/mm²*day clamped between the two layers of TPT.

### Example 11

The solar cell module is manufactured according to the method in Example 1, but the difference compared with Example 1 lies in that the back plate consists of two layers of TPT and a PIB rubber layer with a water vapor transmission rate of 0.01 mg/mm²*day clamped between the two layers of TPT.

### Comparison Example 3

The solar cell module is manufactured according to the method in Example 1, but the difference compared with Example 1 lies in that the back plate is a TPT back plate with a water vapor transmission rate of 2270 mg/mm²*day.

### Comparison Example 4

The solar cell module is manufactured according to the method in Example 1, but the difference compared with Example 1 lies in that the back plate is a TPT back plate with a water vapor transmission rate of 2400 mg/mm²*day.

Performance Test

Damp-heat aging (higher temperature and high humidity): tested in a hot and humid test chamber (85° C./85% RH);

Test object: the solar cell modules obtained according to the embodiments and the comparison examples. The test result of damp-heat aging is shown in Table 1.

TABLE 1

| | One month in | DH | DH | DH | DH |
|---|---|---|---|---|---|
| Product | the open air | 1000 h | 2000 h | 3000 h | 4000 h |
| Example 1 | ok | ok | ok | ok | ok |
| Example 8 | ok | ok | ok | ok | ok |
| Example 9 | ok | ok | ok | ok | ok |
| Example 10 | ok | ok | ok | ok | nigrescence |
| | | | | | of welding |
| | | | | | wires |
| Example 11 | ok | ok | ok | ok | ok |
| Comparison | nigrescence of | / | / | / | / |
| example 3 | welding wires | | | | |
| Comparison | nigrescence of | / | / | / | / |
| example 4 | welding wires | | | | |

In the table, “ok” represents that no bad phenomenon (nigrescence of welding wires, delamination, etc.) occurs to the appearance; power attenuation is less than 2% at DH 1000 h and is less than 5% at DH 5000 h.

“Nigrescence of welding wires” refers to that the welding strength between the welding wires and the cells is reduced, which may result in insufficient welding points, and thus affect the safety and electrical property of the module.

Performance Test

PCT (damp-heat aging): tested in a hot and humid test chamber (110° C./100% RH/1.5 atm);

Test object: samples packaged as the solar cell modules. The test result of damp-heat aging of PCT is shown in Table 2.

TABLE 2

| Product | PCT 50 h |
|---|---|
| Example 1 | Ok |
| Example 8 | Ok |
| Example 9 | Ok |
| Example 10 | Ok |
| Example 11 | Ok |
| Comparison example 3 | Nigrescence of welding wires |
| Comparison example 4 | Nigrescence of welding wires |

In the table, “Ok” represents that no bad phenomenon occurs to the appearance; power attenuation is less than 2% at PCT 50 h and is less than 5% at PCT 100 h.

### Testing Example 1

(1) whether the metal wire in the solar cell module drifts is observed with the naked eyes;

(2) according to the method disclosed in IEC904-1, the solar cell modules manufactured in the above examples and the comparison example are tested with a single flash simulator under standard test conditions (STC): 1000 W/m² of light intensity, AM1.5 spectrum, and 25° C. The photoelectric conversion efficiency of each cell is recorded. The test result is shown in Table 3.

TABLE 3

| Solar cell | | Comparison | Comparison | | | | | | |
|---|---|---|---|---|---|---|---|---|---|
| module | Example 1 | example 1 | example 2 | Example 2 | Example 3 | Example 4 | Example 5 | Example 6 | Example 7 |
| Metal wire | no | Slightly | Slightly | no | no | no | no | no | no |
| drifting | | | | | | | | | |
| phenomenon | | | | | | | | | |
| Photoelectric | 16.70% | 15.70% | 15.30% | 16.80% | 17.20% | 16.95% | 17.00% | 16.80% | 17.10% |
| conversion | | | | | | | | | |
| efficiency | | | | | | | | | |
| Series | 445 | 482 | 515 | 451 | 427 | 436 | 433 | 448 | 442 |
| resistance | | | | | | | | | |
| (mΩ) | | | | | | | | | |
| Fill factor | 0.783 | 0.756 | 0.742 | 0.779 | 0.793 | 0.792 | 0.79 | 0.781 | 0.788 |
| Open-circuit | 37.75 | 37.63 | 37.52 | 37.84 | 37.9 | 37.85 | 37.86 | 37.81 | 37.85 |
| voltage (V) | | | | | | | | | |
| Short-circuit | 9.085 | 8.879 | 8.836 | 9.166 | 9.198 | 9.094 | 9.143 | 9.154 | 9.22 |
| current (A) | | | | | | | | | |
| Working | 31.34 | 30.44 | 30.32 | 31.54 | 31.97 | 31.62 | 31.76 | 31.69 | 31.86 |
| voltage (V) | | | | | | | | | |
| Working | 8.571 | 8.296 | 8.117 | 8.568 | 8.651 | 8.622 | 8.61 | 8.53 | 8.633 |
| current (A) | | | | | | | | | |
| Power (W) | 268.6 | 252.5 | 246.1 | 270.2 | 276.6 | 272.6 | 273.4 | 270.3 | 275 |

The fill factor refers to a ratio of the power at the maximum power point of the solar cell module and the maximum power theoretically at zero resistance, and represents the proximity of the actual power with respect to the theoretic maximum power, in which the greater the value is, the higher the photoelectric conversion efficiency is. Generally, the series resistance is small, so the fill factor is great. The photoelectric conversion efficiency refers to a ratio of converting the optical energy into electric energy by the module under a standard lighting condition (1000 W/m² of light intensity). The series resistance is equivalent to the internal resistance of the solar module, in which the greater the value is, the poorer the performance of the module is. The fill factor represents a ratio of the actual maximum power and the theoretical maximum power of the module, in which the greater the value is, the better the performance of the module is. The open-circuit voltage refers to the voltage of the module in an open circuit under a standard lighting condition. The short-circuit current refers to the current of the module in a short circuit under a standard lighting condition. The working voltage is the output voltage of the module working with the largest power under a standard lighting condition. The working current is the output current of the module working with the largest power under a standard lighting condition. The power is the maximum power which the module can reach under a standard lighting condition.

It can be indicated from Table 3 that for the solar cell module according to the embodiments of the present disclosure, the metal wire will not drift, and higher photoelectric conversion efficiency can be obtained.

In the specification, it is to be understood that terms such as “central,” “longitudinal,” “lateral,” “length,” “width,” “thickness,” “upper,” “lower,” “front,” “rear,” “left,” “right,” “vertical,” “horizontal,” “top,” “bottom,” “inner,” “outer,” “clockwise,” and “counterclockwise” should be construed to refer to the orientation as then described or as shown in the drawings under discussion. These relative terms are for convenience of description and do not require that the present disclosure be constructed or operated in a particular orientation.

In addition, terms such as “first” and “second” are used herein for purposes of description and are not intended to indicate or imply relative importance or significance or to imply the number of indicated technical features. Thus, the feature defined with “first” and “second” may comprise one or more of this feature. In the description of the present disclosure, “a plurality of” means two or more than two, unless specified otherwise.

In the present disclosure, unless specified or limited otherwise, a structure in which a first feature is “on” or “below” a second feature may include an embodiment in which the first feature is in direct contact with the second feature, and may also include an embodiment in which the first feature and the second feature are not in direct contact with each other, but are contacted via an additional feature formed therebetween. Furthermore, a first feature “on,” “above,” or “on top of” a second feature may include an embodiment in which the first feature is right or obliquely “on,” “above,” or “on top of” the second feature, or just means that the first feature is at a height higher than that of the second feature; while a first feature “below,” “under,” or “on bottom of” a second feature may include an embodiment in which the first feature is right or obliquely “below,” “under,” or “on bottom of” the second feature, or just means that the first feature is at a height lower than that of the second feature.

Reference throughout this specification to “an embodiment,” “some embodiments,” or “some examples” means that a particular feature, structure, material, or characteristic described in connection with the embodiment or example is included in at least one embodiment or example of the present disclosure. Thus, these terms throughout this specification do not necessarily refer to the same embodiment or example of the present disclosure. Furthermore, the particular features, structures, materials, or characteristics may be combined in any suitable manner in one or more embodiments or examples.

Although embodiments of the present disclosure have been shown and described, it would be appreciated by those skilled in the art that changes, modifications, alternatives and variations can be made in the embodiments without departing from the scope of the present disclosure.

What is claimed is:

1. A solar cell module, comprising an upper glass plate, a front adhesive layer, a solar cell array, a back adhesive layer and a back plate superposed in sequence, wherein the back plate is a water vapor insulation back plate having a transmission rate less than or equal to 0.1 mg/m²/day; the solar cell array comprises a plurality of cells and conductive wires, adjacent cells being connected by the conductive wires; the cells are provided with secondary grid lines on front surfaces thereof, the conductive wires being welded with the secondary grid lines by a welding layer with an alloy, and the alloy containing Sn and Bi.

2. The solar cell module according to claim 1, wherein the water vapor insulation back plate is a glass or metal plate.

3. The solar cell module according to claim 1, wherein adjacent cells are connected by a metal wire which extends reciprocally between a surface of a first cell and a surface of a second cell adjacent to the first cell, so as to form the plurality of conductive wires.

4. The solar cell module according to claim 1, wherein the alloy further contains at least one of Cu, In, Ag, Sb, Pb and Zn.

5. The solar cell module according to claim 4, wherein based on the total weight of the alloy, there are 15 to 60 weight percent of Bi, 30 to 75 weight percent of Sn, 0 to 20 weight percent of Cu, 0 to 40 weight percent of In, 0 to 3 weight percent of Ag, 0 to 20 weight percent of Sb, 0 to 10 weight percent of Pb, and 0 to 20 weight percent of Zn.

6. The solar cell module according to claim 5, wherein the alloy is at least one selected from 50% Sn-48% Bi-1.5% Ag-0.5% Cu, 58% Bi-42% Sn, and 65% Sn-20% Bi-10% Pb-5% Zn.

7. The solar cell module according to claim 1, wherein the metal wire extends reciprocally between a front surface of the first cell and a back surface of the second cell; a back electrode is disposed on a back surface of the cell, and the metal wire is welded with the back electrode on the second cell.

8. The solar cell module according to claim 1, wherein there is one metal wire.

9. The solar cell module according to claim 1, wherein the cells are arranged in an n×m matrix form, n representing a column, and m representing a row, and m−1≧a≧1;
in a row of cells, the metal wire extends reciprocally between a surface of a first cell and a surface of a second cell adjacent to the first cell; in two adjacent rows of cells, the metal wire extends reciprocally between a surface of a cell in an a^{th} row and a surface of a cell in an (a+1)^{th} row.

10. The solar cell module according to claim 9, wherein in a row of cells, the metal wire extends reciprocally between a front surface of the first cell and a back surface of the second cell adjacent to the first cell;
in two adjacent rows of cells, the metal wire extends reciprocally between a front surface of the cell at the end of the a^{th} row and a back surface of the cell at the end of the (a+1)^{th} row, to connect the two adjacent rows of cells in series; there is a metal wire extending reciprocally between adjacent cells in a row; and there is a metal wire extending reciprocally between cells in adjacent rows.

11. The solar cell module according to claim 1, wherein the front adhesive layer and the back adhesive layer are silica gel.

12. The solar cell module according to claim 1, wherein the water vapor insulation back plate is applied with a white reflective coating inside.

13. The solar cell module according to claim 1, wherein peripheries of the upper glass plate and the water vapor insulation back plate are sealed by clamping a sealant of butyl rubber or polyisobutylene rubber.

14. The solar cell module according to claim 13, wherein the peripheries of the upper glass plate and the water vapor insulation back plate are fixed by silica gel or butyl rubber or double-sided sticky tape via a U-shape frame, and a sealant is filled between the peripheries of the upper glass plate and the water vapor insulation back plate and the U-shape frame.

15. The solar cell module according to claim 1, wherein the front adhesive layer is in direct contact with the conductive wires and is filled between the adjacent conductive wires.

16. A method for manufacturing a solar cell module, comprising:
superposing an upper glass plate, a front adhesive layer, a cell array, a back adhesive layer and a water vapor insulation back plate in sequence, wherein a front surface of a cell faces the front adhesive layer, a back surface thereof facing the back adhesive layer, and
laminating the superposed layers to obtain a solar cell module,
wherein the solar cell array comprises a plurality of cells and conductive wires, adjacent cells being connected by the conductive wires; the cells are provided with secondary grid lines on front surfaces thereof, the conductive wires being welded with the secondary grid lines by a welding layer with an alloy, and the alloy containing Sn and Bi.

17. The method according to claim 16, wherein adjacent cells are connected by a metal wire which extends reciprocally between a surface of a first cell and a surface of a second cell adjacent to the first cell, so as to form a plurality of conductive wires; the metal wire is welded with a secondary grid line on a front surface of the first cell, and with a back electrode on a back surface of the second cell.

18. The method according to claim 16, wherein the metal wire extends reciprocally under a strain.

19. The method according to claim 16, wherein the cells are arranged in an n×m matrix form, n representing a column, and m representing a row;
in a row of cells, the metal wire extends reciprocally between a surface of a first cell and a surface of a second cell adjacent to the first cell; in two adjacent rows of cells, the metal wire extends reciprocally between a surface of a cell in an a^{th} row and a surface of a cell in an (a+1)^{th} row, and m−1≧a≧1; in two adjacent rows of cells, the metal wire extends reciprocally between a surface of a cell at the end of the a^{th} row and a surface of a cell at the end of the (a+1)^{th} row, the end of the a^{th} row and the end of the (a+1)^{th} row located at the same side of the matrix form.

20. The method according to claim 16, wherein there is a metal wire extending reciprocally between adjacent cells in a row; and there is a metal wire extending reciprocally between cells in adjacent rows.
